(19) United States
(12) Patent Application Publication
(10) Pub. No.: US 2026/0092950 A1
(43) Pub. Date: Apr. 2, 2026

(54) Test Socket for Enhancing Integrated Circuit Testing and Its Manufacturing Method

(71) Applicant: He Chou Technology INC., Hsinchu City (TW)

(72) Inventors: Wei-Been Yu, Hsinchu City (TW); Shao-Chun Tseng, Hsinchu City (TW)

(21) Appl. No.: 19/170,101

(22) Filed: Apr. 4, 2025

(30) Foreign Application Priority Data
Apr. 23, 2024 (TW) 113115168

(51) Int. Cl. G01R 1/04; G01R 1/067; G01R 3/00

(52) U.S. Cl. CPC G01R 1/0466; G01R 1/06716; G01R 3/00

(57) ABSTRACT

A test socket for integrated circuit (IC) testing and a method of manufacturing the test socket are provided. The test socket includes an insulating support structure having a plurality of through holes and a plurality of elastic conductive columns. These conductive columns are partially embedded in the support structure and extend through the through holes to accommodate variations caused by IC package warpage and tolerances in BGA solder ball dimensions. The insulating support structure further includes grooves located adjacent to the through holes, which enhance the compressibility and heat dissipation capability of the test socket. The conductive columns themselves have an elastic structure, with at least a portion of their surfaces covered by an insulating material layer to prevent short circuits. The test socket also features a rigid support frame—made of polyimide, PCB material, or ceramic—and a soft support frame made of silicone, offering both durability and flexibility.

### FIELD OF THE DISCLOSURE

The present invention relates to the field of semiconductor test equipment, and more particularly to a test socket used for the electrical testing of integrated circuits.

### BACKGROUND OF THE INVENTION

Test sockets are a critical component in the semiconductor manufacturing industry, providing the necessary electrical connection between a device under test (DUT) and testing equipment. Conventional test sockets often include a set of conductive pins or spring probes that make contact with corresponding pads on the DUT, thereby establishing an electrical channel for signals during testing.

One challenge in the design of test sockets is the mechanical stress and potential damage caused by repeated insertion and removal of the DUT, as well as the requirement for precise alignment between the test socket and the DUT. Furthermore, with the increasing power and heat generation of modern integrated circuits, test socket designs must also address effective thermal management to prevent overheating and to ensure reliable test results.

Traditional test sockets generally employ a unified support structure surrounding the elastic conductive columns. Under compression, however, the conductive columns tend to expand laterally, and the support structure resists this lateral expansion, thereby limiting the compressibility of the elastic columns. In addition, such a design is not optimal for heat dissipation. This limitation is particularly evident when testing high-power DUTs, as insufficient heat management may lead to inaccurate test results or damage to either the DUT or the test socket itself.

Therefore, there is a need in the market for an improved test socket design that provides enhanced mechanical elasticity and superior thermal management to meet the stringent requirements of modern IC testing.

### SUMMARY OF THE INVENTION

It is an object of the present invention to overcome the deficiencies of the prior art by providing a test socket that offers enhanced mechanical elasticity and excellent heat dissipation, thereby accommodating the significant heat generation during the testing of integrated circuits (ICs).

To achieve the above object and other advantages, in one aspect, the invention provides a test socket for IC testing. The test socket comprises an insulating support structure having a plurality of through holes and a plurality of elastic conductive columns. The elastic conductive columns are embedded within the insulating support structure and extend through the through holes. Each elastic conductive column includes a first portion located beneath the insulating support structure and a second portion located above the insulating support structure. Importantly, the insulating support structure further comprises at least one second through hole interposed between the elastic conductive columns. This second through hole penetrates the insulating support structure to provide deformation space around the elastic conductive columns during compression and to serve as a heat dissipation channel.

In one embodiment, depending on specific test requirements, the cross-sectional shape of the second through hole in the test socket may be circular, square, or any other irregular shape. Moreover, the test socket may comprise a combination of a rigid support structure and a soft support structure. The rigid support structure may be composed of materials such as polyimide, PCB, ceramic, or combinations thereof, while the soft support structure may be made of silicone to provide elasticity and compressibility.

In another embodiment, the invention also covers a manufacturing method for the test socket. The method includes forming a multilayer structure that includes at least one insulating support layer, creating a plurality of first through holes in the multilayer structure, filling the first through holes with an elastic conductive adhesive to form the elastic conductive columns, and forming at least one second through hole in the insulating support layer between the first through holes. The total cross-sectional area of the second through holes may be at least 20% of the total cross-sectional area of the test socket, ensuring proper thermal management during testing.

The method may further include forming a sacrificial layer within the multilayer structure and subsequently removing the sacrificial layer, which assists in forming the second through holes or other structural features of the test socket.

Due to the above structure and manufacturing method, the test socket of the present invention offers improved durability, enhanced thermal management, and superior electrical performance. These advantages are particularly important for testing today's high-performance ICs.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1A is a top view of one embodiment of the test socket of the present invention.

FIG. 1B is a partial cross-sectional view of the test socket shown in FIG. 1A.

FIG. 2A is a top view of another embodiment of the test socket of the present invention.

FIG. 3 is a flowchart illustrating the manufacturing method of the test socket according to the embodiment shown in FIG. 2A.

FIGS. 4A to 4D are schematic diagrams corresponding to the various steps in the flowchart of FIG. 3.

FIG. 5 is a flowchart illustrating the manufacturing method of the test socket according to the embodiment shown in FIG. 1A.

FIGS. 6A to 6E are schematic diagrams corresponding to the various steps in the flowchart of FIG. 5.

FIGS. 7A and 7B illustrate two additional configurations of test sockets according to the present invention.

FIGS. 8A and 8B illustrate two further configurations of test sockets according to the present invention.

### LIST OF REFERENCE SYMBOLS

100: Test socket
110: Insulating support structure
112: First through hole
114: Second through hole
120: Elastic conductive column
122: First portion of the elastic conductive column
124: Second portion of the elastic conductive column
200: Test socket
210: Insulating support structure
210′: Multilayer structure
211: Rigid support structure
211′: Rigid support layer
212: First through hole
213: Soft support structure
213′: Soft support layer
214: Second through hole
300: Test socket
311: Rigid support structure
313: Soft support structure
400: Test socket
411: Rigid support structure
413: Soft support structure

### DESCRIPTION OF THE PREFERRED EMBODIMENTS

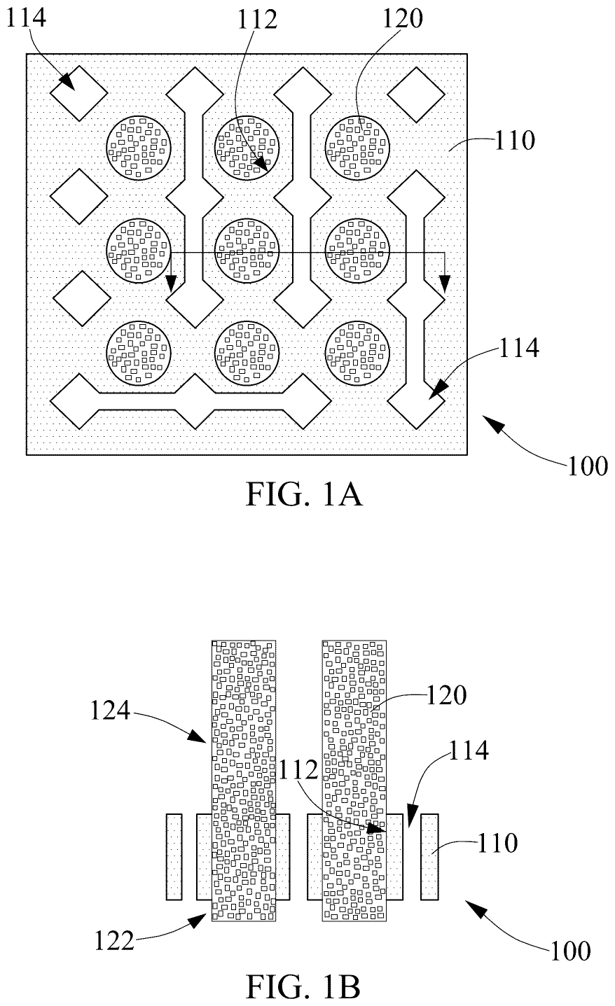

Reference is now made to FIGS. 1A and 1B. In FIG. 1A, a top view of one embodiment of the test socket 100 of the present invention is shown, and FIG. 1B shows a partial cross-sectional view of the test socket 100 of FIG. 1A. In this embodiment, the test socket 100 comprises an insulating support structure 110 and elastic conductive columns 120 that are embedded in the insulating support structure 110 and are configured to extend through a plurality of first through holes 112. The insulating support structure 110 serves as the foundation of the test socket 100, ensuring that the elastic conductive columns 120 are properly positioned and electrically isolated from one another. The lower contact end 122 of the elastic conductive columns 120 contacts the device under test (i.e., the IC), while the upper contact end 124 of the elastic conductive columns 120 makes contact with a printed circuit board used for testing. The elastic conductive columns are capable of being compressed to accommodate changes in IC package height or warpage without affecting the electrical connection with the test board, thereby ensuring reliable electrical contact under the applied test pressure.

In this embodiment, the insulating support structure 110 is primarily made of an electrically insulating polymer, such as polyimide, which is chosen for its high heat resistance and mechanical stability. In other embodiments, the insulating support structure 110 may be formed from alternative materials, such as thermosetting plastics, liquid crystal polymers, or ceramics.

In addition, the test socket 100 includes a second through hole 114 that penetrates the entire thickness of the insulating support structure 110 and is located between the elastic conductive columns 120. The second through hole 114 serves multiple functions. When the elastic conductive columns 120 are compressed and laterally expand, the second through hole 114 provides a buffer space to accommodate the expansion. Importantly, the second through hole 114 also serves as a channel for heat dissipation. More specifically, the second through hole 114 facilitates airflow and heat dispersion, which is critical when testing high-power ICs that generate substantial heat. Moreover, to further enhance cooling efficiency and to account for material expansion and compression during testing, the size, shape, and arrangement of the second through hole 114 may be varied. In the illustrated embodiment, the second through hole 114 is circular, although it may also be square, elliptical, or of any other customized shape. The location of the second through hole 114 is determined through careful simulation and/or experimental analysis to optimize the heat dissipation path, ensuring that hot air is expelled and cool air circulates around the IC and the elastic conductive columns 120.

The test socket 100 of this embodiment is particularly suited for high-power IC testing. With high-power ICs becoming more prevalent in current technology, improved thermal management is essential to maintain proper functionality and reliability during testing.

In summary, the test socket 100 of the present invention provides several significant advantages over conventional test socket designs. First, the inclusion of the second through hole 114 between the elastic conductive columns 120 significantly improves the heat dissipation capability of the test socket 100, effectively dispersing the heat generated by high-power integrated circuits to reduce the risk of overheating and potential test inaccuracies. Second, the enhanced compressibility of the elastic conductive columns 120 ensures that the test socket 100 can accommodate ICs with varying solder ball heights and tolerances, providing a reliable test solution.

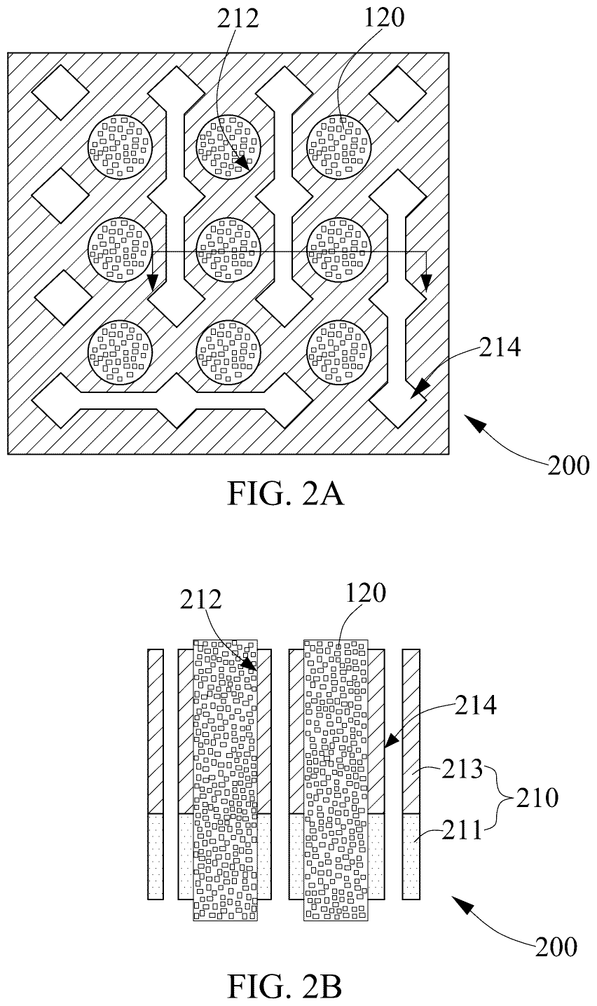

Reference is now made to FIGS. 2A and 2B. In FIG. 2A, a top view of another embodiment of the test socket 200 of the present invention is shown, and FIG. 2B is a partial cross-sectional view of the test socket 200 of FIG. 2A. The insulating support structure 210 of the test socket 200 comprises a rigid support structure 211 and a soft support structure 213, thereby providing a balance between strength and elasticity. The rigid support structure 211 is primarily made of a rigid material, such as polyimide, PCB material, or ceramic, to provide the necessary structural integrity, whereas the soft support structure 213 is made of a flexible material, such as silicone, which absorbs mechanical stress. This combination of rigid and soft materials ensures that the test socket 200 maintains a long service life and reliability even after repeated use. In this embodiment, the rigid support structure 211 is positioned at the periphery of the test equipment, where high structural integrity is generally required. Conversely, the soft support structure 213, which may be made of silicone or another elastomer, is integrated in the area where the elastic conductive columns 120 protrude from the rigid support structure 211, thereby providing a cushioning effect.

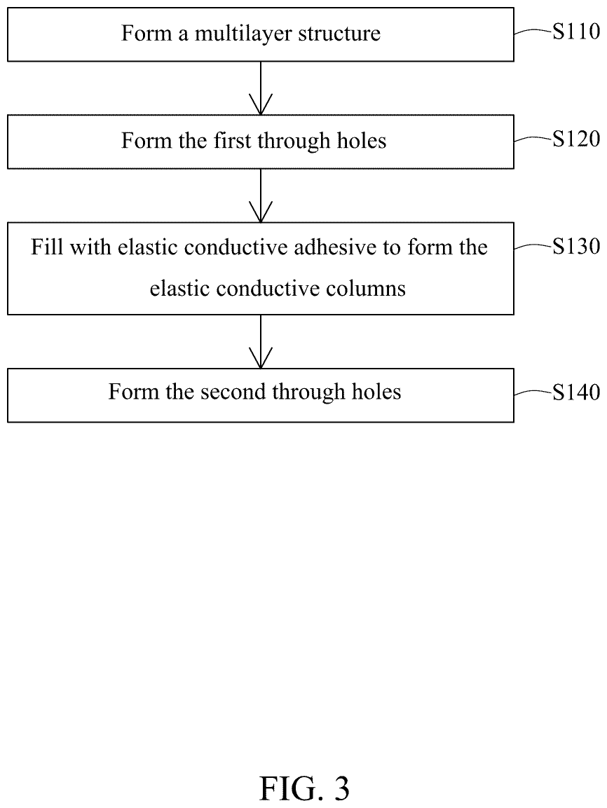

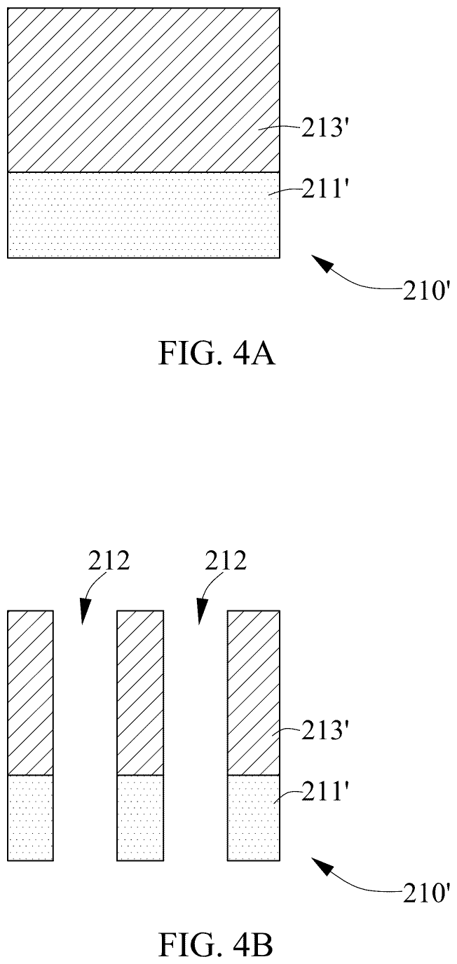

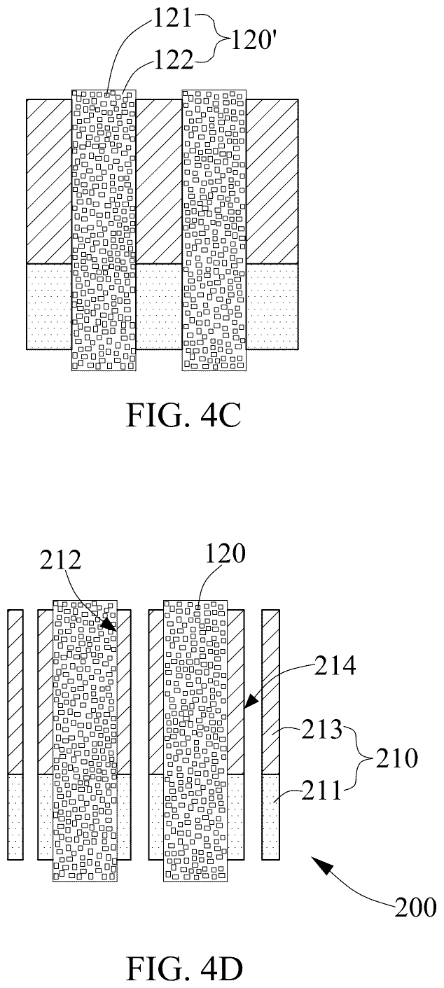

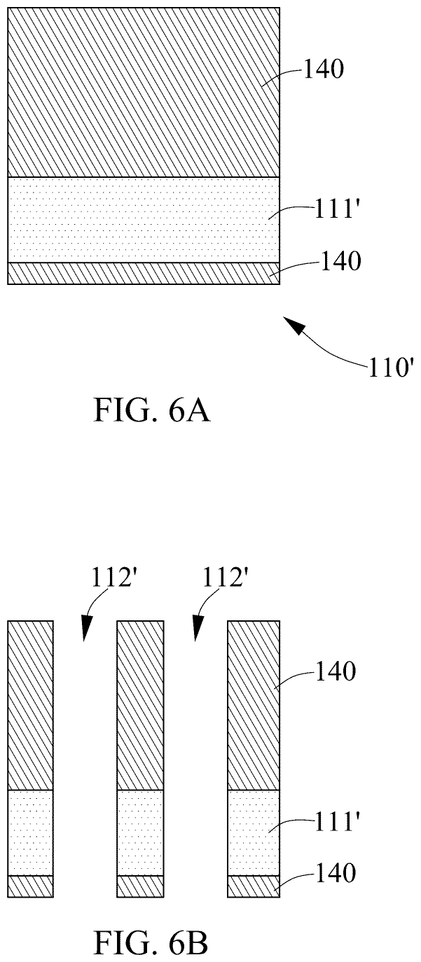

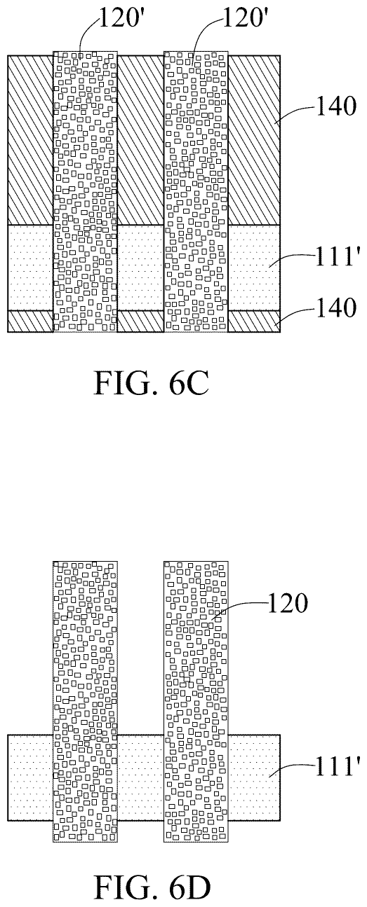

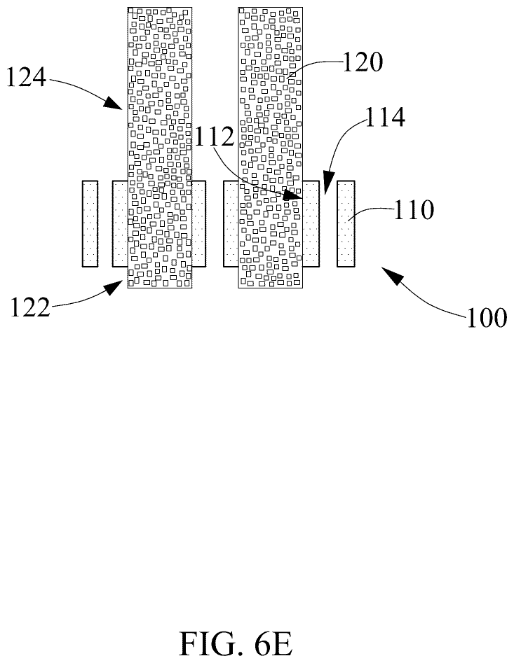

Next, the manufacturing method of the test socket 200 will be described. Reference is made to FIG. 3 and FIGS. 4A to 4D. FIG. 3 is a flowchart illustrating the manufacturing method for the test socket 200 as described in FIG. 2A, and FIGS. 4A to 4D are schematic diagrams corresponding to the various steps in the flowchart of FIG. 3. First, as shown in step S110 and FIG. 4A, a multilayer structure 210′ is formed, which serves as the basis for the insulating support structure 210 of the test socket 200. The multilayer structure 210′ may include a rigid support layer 211′ and a soft support layer 213′. In another embodiment, the multilayer structure 210′ may also include a sacrificial layer (not illustrated in FIGS. 4A to 4D, but see the sacrificial layer 140 in FIGS. 6A to 6E). The formation of the multilayer structure 210′ may involve lamination, molding, or additive manufacturing techniques to combine materials such as polyimide, silicone, and ceramic into a tightly bonded multilayer structure 210′. This process allows for the integration of different materials within the same support structure to optimize electrical insulation and heat management in the test socket 200.

Next, as shown in step S120 and FIG. 4B, after forming the multilayer structure 210′, a plurality of first through holes 212 are formed in the structure. These first through holes 212 are designed to accommodate the elastic conductive columns 120. The first through holes 212 may be formed by precision machining or laser cutting. Then, as shown in step S130 and FIG. 4C, after forming the first through holes 212, an elastic conductive adhesive 120′ is filled into the first through holes 212 to form the elastic conductive columns 120. This elastic conductive adhesive 120′ is typically a composite material in which conductive particles 121 are suspended in an elastomeric matrix 122, providing both conductivity and mechanical elasticity. In this step, the filling process must be carefully controlled to ensure that the elastic conductive adhesive 120′ completely fills the first through holes 212, thereby forming uniformly shaped elastic conductive columns 120 with minimal bubbles or voids that might affect performance. After the elastic conductive adhesive 120′ cures to form the elastic conductive columns 120, a partial etching of the rigid support layer 211′ and the soft support layer 213′ or removal of the sacrificial layer may be performed to expose a portion of the volume of the elastic conductive columns 120.

Next, as shown in step S140 and FIG. 4D, after the elastic conductive columns 120 have been formed, the manufacturing process continues with the formation of second through holes 214. These second through holes 214 are designed for thermal management, allowing effective airflow and heat dissipation during IC testing. In this embodiment, the second through holes 214 may be fabricated using techniques similar to those employed for forming the first through holes 212. Upon completion of step S140, the fabrication of the test socket 200 is substantially complete.

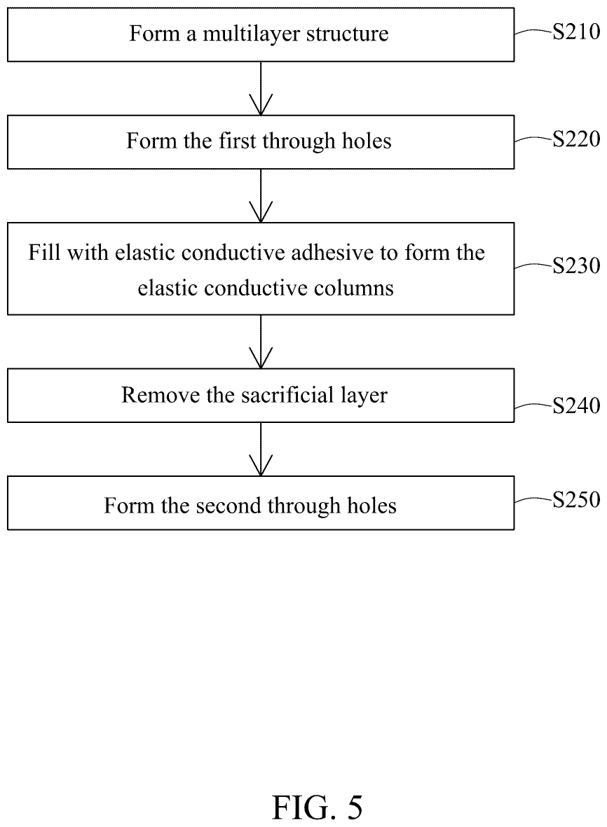

Subsequently, the manufacturing method of the test socket 100 will be described. Reference is now made to FIG. 5 and FIGS. 6A to 6E. FIG. 5 is a flowchart illustrating the manufacturing method for the test socket 100 as described in FIG. 1A, and FIGS. 6A to 6E are schematic diagrams corresponding to the various steps in the flowchart of FIG. 5. First, as shown in step S210 and FIG. 6A, a multilayer structure 110′ is formed. In this structure, a rigid support layer 111′ forms the basis for the insulating support structure 110 of the test socket 100. In addition, the multilayer structure 110′ includes a sacrificial layer 140.

Next, as shown in step S220 and FIG. 6B, after forming the multilayer structure 110′, a plurality of first through holes 112′ are formed, which are designed to accommodate the elastic conductive columns 120. The first through holes 112′ may be formed by precision machining or laser cutting. Then, as shown in step S230 and FIG. 6C, after the formation of the first through holes 112′, an elastic conductive adhesive 120′ is filled into the first through holes 112′ to form the elastic conductive columns 120.

Next, as shown in step S240 and FIG. 6D, after the elastic conductive columns 120 have been formed, the sacrificial layer 140 is removed. The removal of the sacrificial layer 140 may involve chemical dissolution, laser ablation, or mechanical methods (e.g., peeling). Subsequently, as shown in step S250 and FIG. 6E, the manufacturing process continues with the formation of the second through holes 114. Upon completion of step S250, the fabrication of the test socket 100 is substantially complete. In another embodiment, the order of steps S240 and S250 may be interchanged. That is, after forming the elastic conductive columns 120 in step S230, the second through holes 114 may be formed first in step S250, followed by the removal of the sacrificial layer in step S240; the resulting structure is equivalent.

In the above embodiments, the shape of the second through holes 114 and 214 is circular; however, other shapes—such as elliptical, hexagonal, or other custom shapes—may be used. As long as the second through holes 114 and 214 penetrate the support layers, the objective of enhancing the compressibility of the elastic conductive columns and improving heat dissipation is achieved.

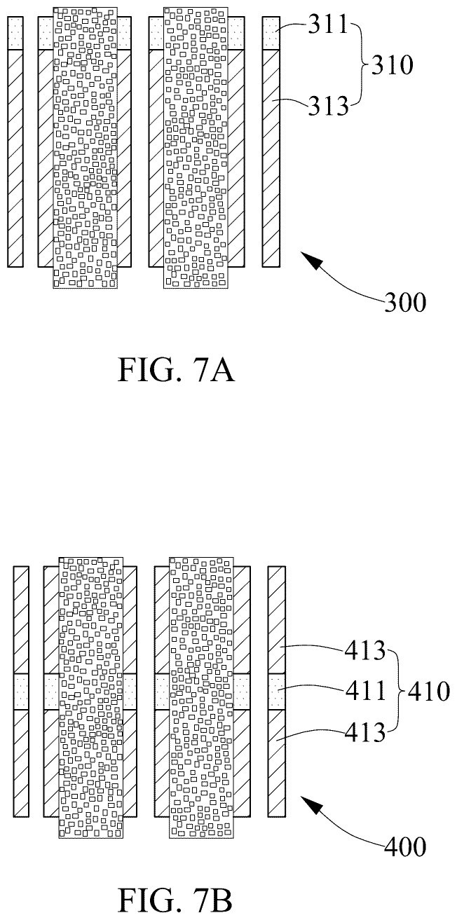

Furthermore, using a manufacturing method similar to the one described above, other types of test sockets may be produced. Reference is now made to FIGS. 7A and 7B, which illustrate two different configurations of test sockets, namely, test socket 300 and test socket 400. The primary difference between test socket 300 and test socket 200 is that the soft support structure 313 in test socket 300 is located beneath the rigid support structure 311, whereas test socket 400 is characterized by having the soft support structure 413 located both above and below the rigid support structure 411.

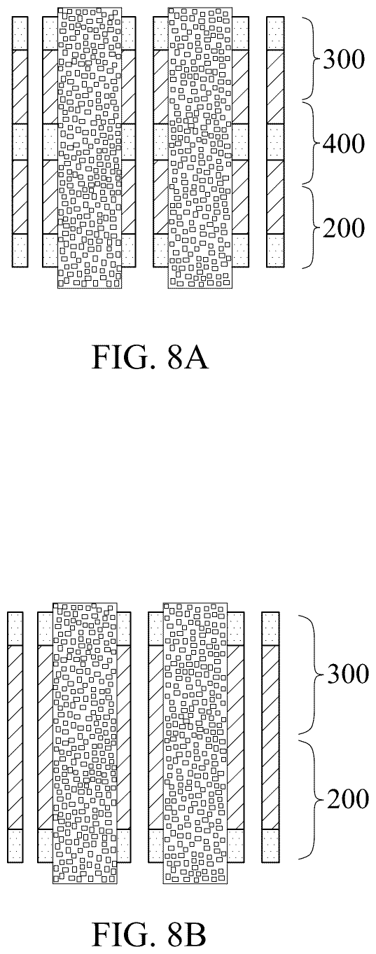

Additionally, combinations of the above-described test sockets may be stacked to meet various testing requirements. For example, FIG. 8A illustrates a vertical integration that combines the features of test sockets 300, 400, and 200. Alternatively, FIG. 8B shows a vertical integration combining the features of test sockets 300 and 200.

In summary, the test sockets and their combinations as described herein provide a multifunctional platform suitable for developing test sockets for various electronic devices, ensuring precise requirements for insulation and electrical contact are met. Compared with conventional test solutions, the test socket of the present invention primarily provides the following two advantages:
1. Enhanced Thermal Management: By incorporating innovative design elements—such as additional second through holes and material selections—the test socket effectively dissipates the heat generated during testing, reducing the risk of overheating and ensuring more accurate test results.
2. Improved Mechanical Elasticity and Durability: The use of second through holes and soft support structures provides the test socket with the necessary elasticity to accommodate ICs of various sizes and tolerances, while also ensuring sufficient durability for repeated use.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

1. A test socket for IC testing, comprising:
an insulating support structure including a plurality of first through holes; and
a plurality of elastic conductive columns disposed in and filling the first through holes;
wherein at least one second through hole penetrates the insulating support structure and is formed between the elastic conductive columns.

2. The test socket of claim 1, wherein the cross-sectional shape of the second through hole is circular, square, or any other irregular shape.

3. The test socket of claim 1, wherein the insulating support structure comprises a rigid support structure and a soft support structure.

4. The test socket of claim 3, wherein the rigid support structure is selected from the group consisting of polyimide, PCB material, ceramic, or combinations thereof.

5. The test socket of claim 3, wherein the soft support structure is made of silicone.

6. The test socket of claim 1, wherein the total cross-sectional area of the second through hole is not less than 20% of the cross-sectional area of the test socket.

7. A method for manufacturing a test socket for IC testing, the method comprising:
forming a multilayer structure comprising at least one insulating support layer;
forming a plurality of first through holes in the multilayer structure;
filling the first through holes with an elastic conductive adhesive; and
forming at least one second through hole in the insulating support layer between the first through holes, the second through hole penetrating the insulating support layer.

8. The method of claim 7, further comprising forming at least one sacrificial layer in the multilayer structure.

9. The method of claim 8, further comprising removing the sacrificial layer.

10. The method of claim 7. wherein the total cross-sectional area of the second through hole is not less than 20% of the cross-sectional area of the test socket.

11. The method of claim 7, wherein the insulating support structure comprises a rigid support structure and a soft support structure.

12. The method of claim 11, wherein the rigid support structure is selected from the group consisting of polyimide, PCB material, ceramic, or combinations thereof.

13. The method of claim 11, wherein the soft support structure is made of silicone.
